(19) United States
(12) Patent Application Publication
(10) Pub. No.: US 2024/0402266 A1
(43) Pub. Date: Dec. 5, 2024

(54) VECTOR MAGNETIC SENSOR BASED ON A STRETCHABLE WHISPERING GALLERY MODE MICRORESONATOR

(71) Applicant: Soreq Nuclear Research Center, Yavne (IL)

(72) Inventors: Eyal Yacoby, Yavne (IL); Yosef London, Yavne (IL); Yekutiel Meshorer, Yavne (IL)

(73) Assignee: Soreq Nuclear Research Center, Yavne (IL)

(21) Appl. No.: 18/718,441

(22) PCT Filed: Dec. 13, 2022
(86) PCT No.: PCT/IB2022/062131

§ 371 Date: Jun. 11, 2024

Related U.S. Application Data
(60) Provisional application No. 63/289,732, filed on Dec. 15, 2021.

(51) Int. Cl. G01R 33/032

(52) U.S. Cl. CPC G01R 33/0327

(57) ABSTRACT

An apparatus includes a light source, an optical fiber, having a tapered region, coupled to the light source, a stretchable microresonator in contact with the tapered region of the fiber and in contact with a magnetostrictive material, and a polarization controller that controls polarization of light in the tapered region.

### FIELD OF THE INVENTION

The present invention relates generally to optical vector magnetometers.

### BACKGROUND OF THE INVENTION

Highly sensitive and low cost magnetometers are available. Tiny and very low cost magnetometers based on the “Hall effect” have high sensitivities and a typical resolution of a few hundreds of nT. However, the fact that these kinds of magnetometers have electrical wires and the fact that they cannot be remotely controlled are significant drawbacks.

### SUMMARY

The present invention seeks to provide a new and simple optical vector magnetometer based on an ultra-high Q Whispering Gallery Mode (WGM) microresonators.

The majority of WGM-based magnetometers can be categorized into two types: magneto-optical and optomechanical sensors. Magneto-optical magnetometers use magneto-optical fluids that change their refractive index (RI) in response to an applied magnetic field. However, the magnetic fluid usually deteriorates the optical quality of the microresonator to typical values of 103-104, greatly diminishing the detection limit of the sensor.

In contrast, optomechanical magnetometers usually employ a magnetostrictive material which changes its shape as a response to an applied magnetic field. By placing the material in contact with the microresonator, the change in its shape applies a mechanical force deforming the microresonator, while preserving the high Q factor.

In one aspect of the invention, a double-tailed microsphere (DTM) strain-gauge is used in order to measure the directional elongation of a magnetostrictive rod under a varying magnetic field. The unique structure of the magnetometer makes it possible to convert a large elongation of a long magnetostrictive rod to a very short DTM, and hence, to improve the sensitivity by orders of magnitude. Furthermore, it provides directional information regarding the magnetic field.

The invention provides a simple and low cost vector magnetometer with the possibility to connect multiple devices to a single optical fiber for quasi distributed sensing.

One embodiment of the invention is a vector magnetometer based on a whispering gallery mode (WGM) double-tailed microsphere (DTM). The DTM, which is a microresonator with mechanical support (e.g., two fiber ends) is used to detect strain induced on a magnetostrictive rod in response to a change in the ambient magnetic field. The strain of the magnetostrictive rod applies a tensile stress, and therefore a strain, on the DTM via its fiber ends. This strain is then converted to a spectral shift of the WGMs of the DTM. The unique structure of the suggested magnetometer makes it possible to convert large elongation of a long magnetostrictive rod to a very short DTM by adding a high strength arm between the DTM and the magnetostrictive rod.

In one embodiment, the invention provides a method in which a stretchable microresonator is connected to a tapered fiber and to a magnetostrictive material. The method includes, without limitation, connecting a magnetostrictive material to a static stage, connecting an arm to the static stage or to an edge of the magnetostrictive material, avoiding any contact between the arm and a central region of the magnetostrictive material, connecting one of the fiber tails of a stretchable microresonator to an edge of the arm, connecting one of the fiber tails of the microresonator to the edge of the magnetostrictive material, and bringing a tapered fiber in contact with the microresonator to achieve optical coupling. The tapered fiber may be transverse to the fiber tails of the stretchable microresonator.

### BRIEF DESCRIPTION OF THE DRAWINGS

The present invention will be understood and appreciated more fully from the following detailed description taken in conjunction with the drawings in which:

FIG. 1 is a simplified schematic illustration of a laser system in accordance with a non-limiting embodiment of the invention, which includes a tunable laser diode 1, a polarization controller (PC) 2, a magnetic sensor 3 based on a double-tailed microsphere, a magnetic coil 4, a power supply 5, a photodetector 6, and an optical spectrum analyzer 7.

FIG. 2 is a simplified schematic illustration of a magnetic sensor in accordance with a non-limiting embodiment of the invention, based on a double-tailed microsphere (DTM) attached to a magnetostrictive rod. A DTM with a length L_{DTM} is attached to a magnetostrictive rod with a length L using a high strength arm. A large elongation of a long TDR is converted to a very short DTM, and hence, achieve a large strain-to-magnetic field ratio. The inset is a picture of an actual device.

FIGS. 3A-3C are simplified graphs of magnetometer sensitivity for L/L_{DTM}8.4 (FIG. 3A), for L/L_{DTM}=5.2 (FIG. 3B), and for L/L_{DTM}=1 (FIG. 3C).

### DETAILED DESCRIPTION

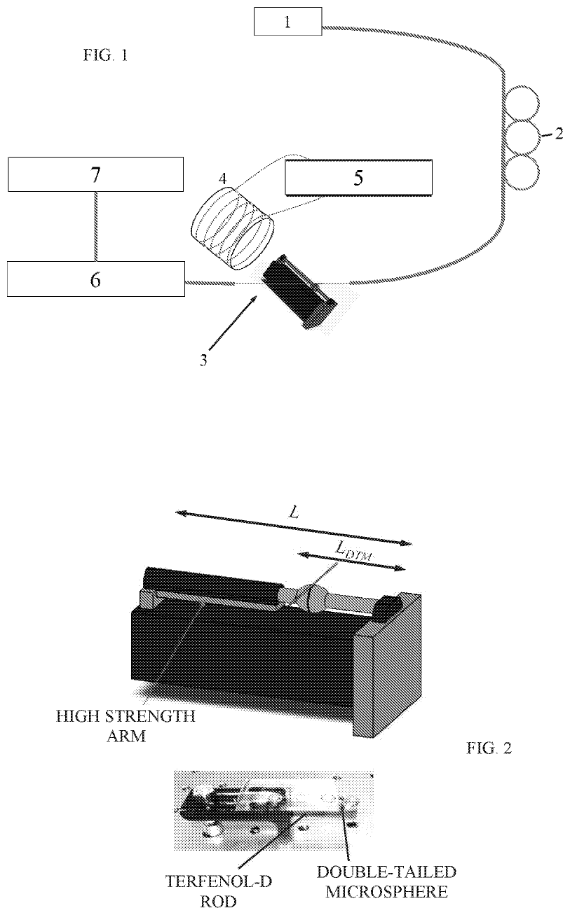

An embodiment of the invention is presented in FIG. 1. A tunable single mode laser is used to measure the shapes and the spectral shifts of the WGMs of the DTMs. Light is coupled to the microspheres using a tapered fiber. A three-pedal polarization controller (PC) between the laser output and the microsphere is used to excite TE and/or TM WGMs.

A DTM with a length L_{DTM} is connected to a magnetostrictive rod of length L. The magnetostrictive rod changes its shape in response to a variation in the magnetic field ΔB and induces a strain ε according to its magnetostriction coefficient ε=α_{B}·ΔB where α_{B} is in units of με/mT. By placing the magnetostrictive material in contact with the microresonator, the change in its shape applies a force on the microresonator which consequently alters its shape and radius as well. The elongation of the DTM, ΔL_{DTM}, is equal to that of the TDR, ΔL. The magnetometer is sensitive only to magnetic fields aligned with the axis of the DTM.

The sensitivity of the magnetometer is improved by increasing the ratio between the length of the magnetostrictive rod, L, and that of the DTM, L_{DTM}. The elongation of the magnetostrictive rod, ΔL, increases linearly with its increase in length. This elongation is, in turn, converted to the DTM; the shorter the DTM, the larger the strain it sustains. L/L_{DTM} is increased by adding a high strength arm as shown in FIG. 2.

### Example

This demonstration uses a tunable single mode laser (velocity, model 6328) with a center wavelength of λ=1550 nm. This laser is used to measure the shapes and the spectral shifts of the WGMs of the DTMs. The Q-factor of the DTMs is on the order of ˜10⁸. Light is coupled to the microspheres using a tapered fiber (SMF28) with a waist diameter of ˜2 μm. Terfenol-D rods are used as a magnetostrictive material (from TdVib LLC). (The invention is not limited to Terfenol-D, and can be carried out with other magnetostrictive materials, such as but not limited to, Galfenol.) A magnetic coil is used to apply a magnetic field along the axis of the TDR (7 mT max). The magnetic field was measured using a 3-axes magnetic sensor (AKM, Hall effect) with a resolution of 100 nT.

Three ratios of L/L_{DTM} are used. A stiff silica slide (1 mm thickness) is connected as a high strength arm to one or both sides of the DTM (see FIG. 2). The laser is repeatedly swept across specific WGMs, detected by a photodetector and monitored with an oscilloscope. The magnetic coil was fed with a square wave of current at a rate of 1 Hz, far slower than the sweeping speed of the optical source.

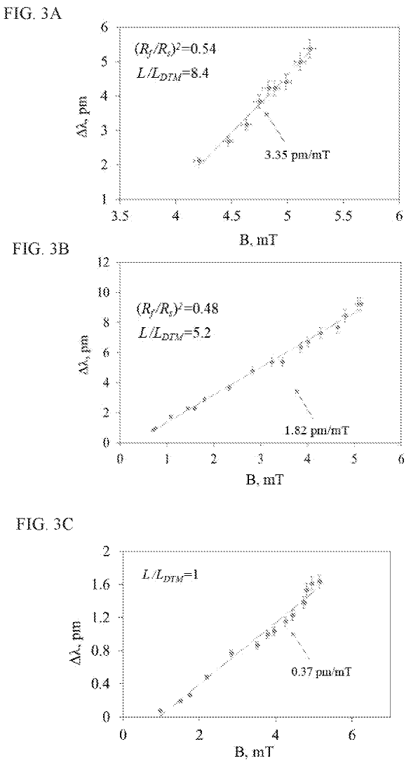

The results shown in FIGS. 3A-3C demonstrate the strong dependence of the magnetometer sensitivity on the L/L_{DTM} ratio. A maximal sensitivity of 3.35 pm/mT is obtained. The minimal detection limit of the sensor in this example can be evaluated via the minimal spectral shift that may be measured. A common metric used is the HWHM of the WGM, which is governed by its Q factor. In the mentioned microspheres the spectral width of the WGMs is on the order of 0.015 pm, resulting in a magnetic detection limit of ˜2 μT. This is not a fundamental metric, and a spectral resolution of even a tenth of the WGM FWHM can be reached.

According to the measured sensitivities presented in FIGS. 3A-3C, the magnetostriction coefficient α_{B} of the TDRs for the magnetic fields used in the experiments is 1.4 με/mT. It has been well established in the literature that the Terfenol-D magnetostriction coefficient is highly dependent on the magnetic field work point. For higher magnetic fields (20-40 mT), α_{B}—and hence the sensitivity of the magnetic sensor—can be increased by a factor of ˜10. This can be achieved by applying a self DC magnetic field on the order of 20 mT using a permanent magnet.

TABLE 1
Relevant parameters in the example

| Parameter | Symbol | Value | |
|---|---|---|---|
| Laser central wavelength | λ₀ | 1550 | nm |
| Microresonator (sphere) diameter | D | 170-180 | μm |
| Microresonator Q factor | Q | 10⁸ | |
| Length of the magnetostrictive rods | L | 20-30 | mm |
| Length of the DTM | L_{DTM} | 2-5 | mm |

What is claimed is:

1. An apparatus comprising:
a light source;
an optical fiber, having a tapered region, coupled to said light source;
a stretchable microresonator in contact with said tapered region of said fiber and in contact with a magnetostrictive material; and
a polarization controller that controls polarization of light in said tapered region.

2. The apparatus according to claim 1, wherein said microresonator comprises a vector magnetometer based on a whispering gallery mode (WGM) double-tailed microsphere (DTM), configured to detect strain induced on said magnetostrictive material in response to a change in the ambient magnetic field.

3. The apparatus according to claim 1, further comprising an arm coupled between said stretchable resonator and said magnetostrictive material.

4. The apparatus according to claim 1, in which a permanent magnetic field is used to increase a sensitivity of said microresonator by increasing a magnetostriction coefficient of said magnetostrictive material.

5. A method in which a stretchable microresonator is connected to a tapered fiber and to a magnetostrictive material, comprising:
connecting a magnetostrictive material to a static stage;
connecting an arm to said static stage or to an edge of said magnetostrictive material, avoiding any contact between said arm and a central region of said magnetostrictive material;
connecting one of the fiber tails of a stretchable microresonator to an edge of said arm;
connecting one of the fiber tails of said microresonator to the edge of said magnetostrictive material; and
bringing a tapered fiber in contact with said microresonator to achieve optical coupling.

6. The method according to claim 5, wherein said tapered fiber is transverse to the fiber tails of said stretchable microresonator.
